(19) United States
(12) Patent Application Publication
(10) Pub. No.: US 2022/0037412 A1
(43) Pub. Date: Feb. 3, 2022

(54) COLOR FILM SUBSTRATE, DISPLAY PANEL, AND DISPLAY DEVICE

(71) Applicant: Shanghai Tianma Micro-Electronics Co., Ltd., Shanghai (CN)

(72) Inventor: Sitao HUO, Shanghai (CN)

(21) Appl. No.: 17/034,431

(22) Filed: Sep. 28, 2020

(30) Foreign Application Priority Data
Jul. 30, 2020 (CN) 202010749180.9

(51) Int. Cl. H01L 27/32

(52) U.S. Cl. CPC H01L 27/322; H01L 27/326

(57) ABSTRACT

A color film substrate, a display panel, and a display device are provided. The color film substrate includes a substrate; a color filter layer disposed on the substrate; and a color conversion layer disposed on a side of the color filter layer away from the substrate. In an area of the color conversion layer corresponding to each pixel unit, the color conversion layer includes at least two color conversion units. Colors of lights generated by color conversion materials of different color conversion units excited by excitation light are different. In a same color conversion unit, a concentration of a color conversion material in a side of the color conversion layer adjacent to the color filter layer is C1, and a concentration of a color conversion material in a side of the color conversion layer away from the color filter layer is C₂, and |C₁−C₂|>0.

### CROSS-REFERENCE TO RELATED APPLICATION

This application claims priority of Chinese Patent Application No. 202010749180.9, filed on Jul. 30, 2020, the entire contents of which are hereby incorporated by reference.

### FIELD OF THE DISCLOSURE

The present disclosure generally relates to the field of display technology and, more particularly, relates to a color film substrate, a display panel, and a display device.

### BACKGROUND

In some display panels, the monochromatic light emitted by the light source irradiates on the color conversion materials of different colors to excite light of different colors, such as red light, green light, and blue light, and these different colors of lights are used to display image. However, some display panels may have a color cast phenomenon, resulting in poor display effects.

Thus, there is need to reduce the color cast phenomenon and optimize the display effects of the display panels. The disclosed color film substrate, display panel, and display device are directed to solve one or more problems set forth above and other problems in the art.

### BRIEF SUMMARY OF THE DISCLOSURE

One aspect of the present disclosure provides a color film substrate. The color film substrate includes a substrate; a color filter layer disposed on the substrate; and a color conversion layer disposed on a side of the color filter layer away from the substrate. The color film substrate is correspondingly disposed with an array substrate having a plurality of pixel units. In an area of the color conversion layer corresponding to each pixel unit of the plurality of pixel units, the color conversion layer includes at least two color conversion units. Colors of lights generated by color conversion materials of different color conversion units of the at least two color conversion units excited by excitation light are different; and in a same color conversion unit of the at least two color conversion units, a concentration of a color conversion material in a side of the color conversion layer adjacent to the color filter layer is C1, a concentration of a color conversion material in a side of the color conversion layer away from the color filter layer is C2; and |C1−C2|>0.

Another aspect of the present disclosure provides a display panel. The display panel may include a color film substrate; and an array substrate disposed opposing to the color film substrate. The color film substrate includes a substrate; a color filter layer disposed on the substrate; and a color conversion layer disposed on a side of the color filter layer away from the substrate. The color film substrate is correspondingly disposed with the array substrate having a plurality of pixel units. In an area of the color conversion layer corresponding to each pixel unit of the plurality of pixel units, the color conversion layer includes at least two color conversion units. Colors of lights generated by color conversion materials of different color conversion units of the at least two color conversion units excited by excitation light are different; and in a same color conversion unit of the at least two color conversion units, a concentration of a color conversion material in a side of the color conversion layer adjacent to the color filter layer is C1, a concentration of a color conversion material in a side of the color conversion layer away from the color filter layer is C2; and |C1−C2|>0. A side of the color filter substrate having the color conversion unit is disposed adjacent to a side of the array substrate having a light-emitting component; the light-emitting component is configured to emit the excitation light; and the excitation light is used to excite the color conversion unit to generate light of a corresponding color.

Another aspect of the present disclosure provides a display device. The display device includes a display panel. The display panel may include a color film substrate; and an array substrate disposed opposing to the color film substrate. The color film substrate includes a substrate; a color filter layer disposed on the substrate; and a color conversion layer disposed on a side of the color filter layer away from the substrate. The color film substrate is correspondingly disposed with the array substrate having a plurality of pixel units. In an area of the color conversion layer corresponding to each pixel unit of the plurality of pixel units, the color conversion layer includes at least two color conversion units. Colors of lights generated by color conversion materials of different color conversion units of the at least two color conversion units excited by excitation light are different; and in a same color conversion unit of the at least two color conversion units, a concentration of a color conversion material in a side of the color conversion layer adjacent to the color filter layer is C1, a concentration of a color conversion material in a side of the color conversion layer away from the color filter layer is C2; and |C1−C2|>0. A side of the color filter substrate having the color conversion unit is disposed adjacent to a side of the array substrate having a light-emitting component; the light-emitting component is configured to emit the excitation light; and the excitation light is used to excite the color conversion unit to generate light of a corresponding color.

Other aspects of the present disclosure can be understood by those skilled in the art in light of the description, the claims, and the drawings of the present disclosure.

### BRIEF DESCRIPTION OF THE DRAWINGS

The following drawings are incorporated in and constitute a part of the specification, illustrating embodiments of the present disclosure, and together with the detailed descriptions serve to explain the mechanism of the present disclosure.

FIG. 1 illustrates a top view of an exemplary color film substrate consistent with various disclosed embodiments of the present disclosure;

FIG. 2 illustrates an exemplary AA-sectional view of the color film substrate in FIG. 1 consistent with various disclosed embodiments of the present disclosure;

FIG. 3 illustrates a cross-sectional view of another exemplary color film substrate consistent with various disclosed embodiments of the present disclosure;

FIG. 4 illustrates a cross-sectional view of another exemplary color film substrate consistent with various disclosed embodiments of the present disclosure;

FIG. 5 illustrates a cross-sectional view of another exemplary color film substrate consistent with various disclosed embodiments of the present disclosure;

FIG. 6 illustrates a cross-sectional view of another exemplary color film substrate consistent with various disclosed embodiments of the present disclosure;

FIG. 7 illustrates a cross-sectional view of another exemplary color film substrate consistent with various disclosed embodiments of the present disclosure;

FIG. 8 illustrates a cross-sectional view of another exemplary color film substrate consistent with various disclosed embodiments of the present disclosure;

FIG. 9 illustrates a cross-sectional view of another exemplary color film substrate consistent with various disclosed embodiments of the present disclosure;

FIG. 10 illustrates a cross-sectional view of another exemplary color film substrate consistent with various disclosed embodiments of the present disclosure;

FIG. 11 illustrates a cross-sectional view of an exemplary display panel consistent with various disclosed embodiments of the present disclosure; and

FIG. 12 illustrates a cross-sectional view of an exemplary display device consistent with various disclosed embodiments of the present disclosure;

### DETAILED DESCRIPTION

Reference will now be made in detail to exemplary embodiments of the disclosure, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all the embodiments of the present disclosure. Based on the disclosed embodiments, persons of ordinary skill in the art may derive other embodiments consistent with the present disclosure, all of which are within the scope of the present disclosure. Further, in the present disclosure, the disclosed embodiments and the features of the disclosed embodiments may be combined when there are no conflicts.

The following description of at least one exemplary embodiment is actually only illustrative, and in no way serves as any limitation to the present disclosure and its application or use.

The technologies, methods, and equipment known to those of ordinary skill in the relevant fields may not be discussed in detail, but where appropriate, the technologies, methods, and equipment should be regarded as part of the specification.

In all the examples shown and discussed herein, any specific value should be interpreted as merely exemplary and not as limiting. Therefore, other examples of the exemplary embodiment may have different values. It should be noted that similar reference numerals and letters indicate similar items in the following drawings, so once a certain item is defined in one drawing, it does not need to be further discussed in subsequent drawings.

As described in the background, some display panels that use the light generated by the color conversion materials for display have serious color cast issue. The main reason for this problem is that the thicknesses of the color conversion materials in these display panels are relatively large, which cause the light with a shorter wavelength of the light emitted from the bottom of the film to have a secondary excitation to the color conversion material on the top of the film. After the secondary excitation, light with a longer wavelength is generated, which causes the color of the generated light to shift, and the display effect is adversely affected.

The present disclosure provides a color film substrate, a display panel and a display device to overcome the above-mentioned problems in the prior art. The color film substrate may include a substrate, and a color filter film on the substrate. Further, the color film substrate may also include a color conversion layer (CCL). In a same pixel unit, the color conversion layer may include at least two color conversion units. The colors of the light generated by the excitation of the color conversion materials in different types of color conversion units excited by the excitation light may be different.

In a same color conversion unit, the concentration of the color conversion material in the side of the color conversion layer adjacent to the color filter layer may be C1, and the concentration of the color conversion material in the side of the color conversion layer away from the color filter layer may be C2, and |C1−C2|>0.

In the same color conversion unit, the concentration of the color conversion material on the side of the color conversion layer adjacent to the color filter layer is C1, and the concentration of the color conversion material on the side of the color conversion layer away from the color filter layer C2, and |C1−C2|>0. Therefore, the color conversion material with a higher concentration may absorb most of the excitation light to produce most of the light required for display. The color conversion material with a lower concentration may reduce the secondary excitation of the color conversion material, which may effectively reduce the color cast issue, and the display effect may be improved.

The above may be the core idea of the present disclosure. To make the above objectives, features and advantages of the present disclosure more obvious and understandable, the technical solutions in the embodiments of the present disclosure will be clearly and completely described below in conjunction with the accompanying drawings in the embodiments of the present disclosure. Obviously, the described embodiments are only a part of the embodiments of the present disclosure, rather than all the embodiments. Based on the embodiments of the present disclosure, all other embodiments obtained by those of ordinary skill in the art without creative work shall fall within the protection scope of the present invention.

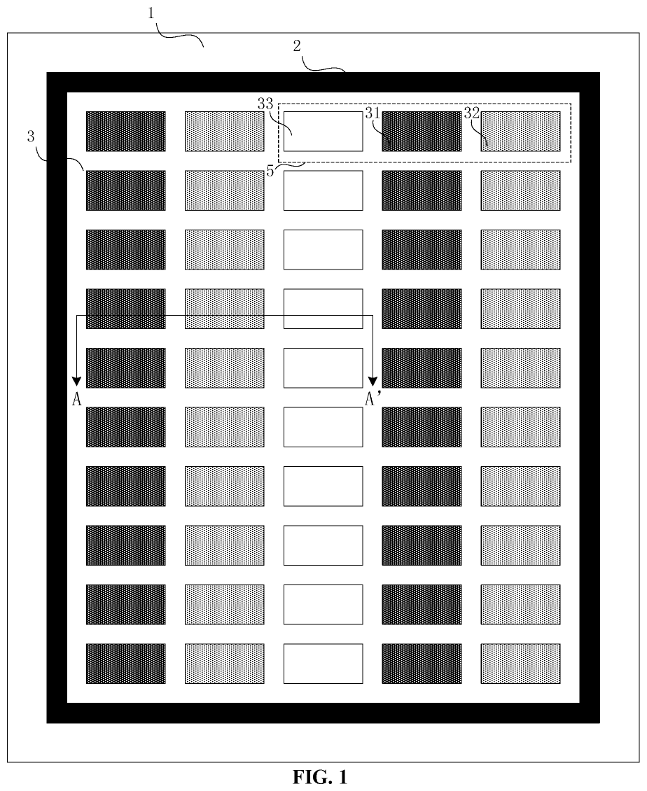

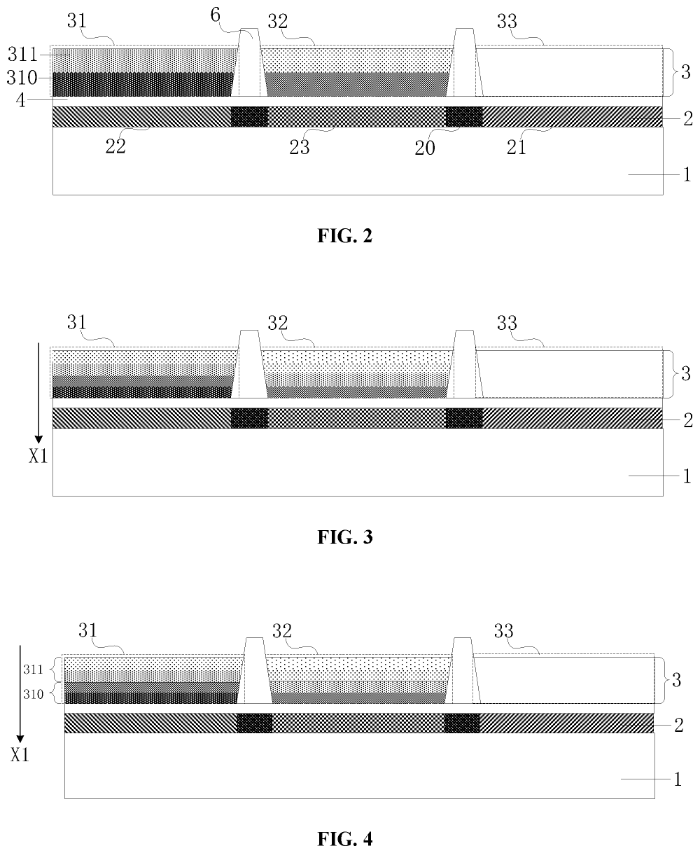

The present disclosure provides a color film substrate. FIG. 1 is a schematic top view of an exemplary color film substrate provided by one embodiment of the present disclosure. FIG. 2 is an AA-sectional view of the color film substrate shown in FIG. 1.

As shown in FIGS. 1-2, the color film substrate may include a substrate 1, a color filter layer 2 on the substrate 1, and a color conversion layer 3 on the side of the color filter layer 2 away from the substrate 1. It should be noted that, there may also be a transparent planar layer 4, etc., between the color filter layer 2 and the color conversion layer 3.

In one embodiment of the present disclosure, the color filter substrate and an array substrate may be arranged correspondingly, and a plurality of pixel units 5 may be disposed on the array substrate. As shown in FIG. 1, in an area corresponding to each pixel unit 5, the color conversion layer 3 may include at least two color conversion units, such as a color conversion unit 31 and a color conversion unit 32. Among them, the color conversion materials in different types of color conversion units may be excited by the excitation light to produce different colors. For example, the color of the light generated by the color conversion material in the color conversion unit 31 excited by the excitation light may be red light. The color of the light generated by the color conversion material in the conversion unit 32 being excited by the excitation light may be green light.

In some embodiments of the present disclosure, when the color conversion layer 3 includes only two color conversion units in the area corresponding to each pixel unit 5, the color conversion layer 3 may also include a transparent unit 33. The transparent unit 33 may be used to transmit the excitation light to excite light, such as blue light, red light and green light, to display images. Further, the transparent unit 33 may include a scattering material to scatter the excitation light transmitted by the transparent unit 33 to expand the exiting angle of the excitation light.

It should be noted that each pixel unit 5 may include a plurality of sub-pixels, and each sub-pixel may be corresponding to a color conversion unit or a transparent unit. As shown in FIG. 2, the color film substrate in one embodiment of the present disclosure may further include a pixel definition layer 6. The pixel definition layer 6 may be configured to divide the color conversion layer 3 into individual color conversion units or transparent units.

In one embodiment of the present disclosure, as shown in FIG. 2, in the same color conversion unit, the concentration of the color conversion material in the side of the color conversion layer 3 adjacent to the color filter layer 2 may be referred as C1, and the concentration of the color conversion material in the side of the color conversion layer 3 away from the color filter layer 2 may be referred to as C2; and |C1−C2|>0. For example, in the color conversion unit 31, the concentration of the color conversion material 310 in the side of the color conversion layer 3 adjacent to the color filter layer 2 may be C1, and the concentration of the color conversion material 311 in the side of the color conversion layer 3 away from the color filter layer 2 may be C2, and |C1−C2|>0.

Based on such a configuration, the color conversion material with a larger concentration may be used to absorb most of the excitation light to produce most of the light required for display, and the color conversion material with a lower concentration may be configured to reduce the secondary excitation of the color conversion material. Thus, the color cast issue may be effectively reduced; and the display effect may be improved.

In some embodiments of the present disclosure, C1−C2>0, and in other embodiments of the present disclosure, C2−C1>0. When C2−C1>0, the color conversion material with a higher concentration, such as 311, may be closer to the light source that generates the excitation light. Because the concentration or density of the color conversion material in the color conversion material with a lower concentration, such as 310, may be smaller, it may greatly reduce the secondary excitation of the light with a shorter wavelength in the light generated by the color conversion material such as 311, to the color conversion material such as 310. Thus, the color cast issue may be effectively reduced. When C1−C2>0, the color conversion material with a lower concentration may be closer to the light source that generates the excitation light. Because the color conversion material with a lower concentration may absorb less excitation light and generates less light, it may greatly reduce the secondary excitation of the light with a shorter wavelength to the color conversion material. Thus, the color cast issue may be effectively reduced, and the display effect may be improved.

Thus, no matter C1−C2>0, or C2−C1>0, in particular, whether the color conversion material with the higher concentration, such as 311, is closer to the light source that generates the excitation light, or the color conversion material with the lower concentration, such as 310, is closer to the light source, as long as the color conversion layer 3 may be divided into two layers of color conversion materials with different concentrations, in particular, into two layers of color conversion materials with different concentrations, that is, into a color conversion material with a higher concentration, such as 311, and a color conversion material with a lower concentration, such as 310, the color cast issue of color conversion layer 3 may be effectively reduced; and the display effect may be improved.

It should be noted that the concentration in the embodiments of the present disclosure may refer to the component of the total amount of the color conversion material in the solution before the color conversion layer 3 is cured and molded. In some embodiments, it may refer to the content of the solid color conversion material in the total amount of the color conversion layer 3 after the color conversion layer 3 is cured and molded. Of course, in some solid color conversion layers 3 that are not solidified by solution, the concentration may also refer to the component of the total color conversion material in the solid color conversion layer 3.

It should also be noted that the color filter layer 2 in the embodiment of the present disclosure may include a black matrix 20 and a color filter unit. The black matrix 20 may define a plurality of sub-pixel regions; and the color filter units may be located in the sub-pixel regions. Further, each color conversion unit or each transparent unit may be arranged corresponding to a color filter unit. For example, the color conversion unit 31 and the color filter unit 22 may be arranged correspondingly, the color conversion unit 32 and the color filter unit 23 may be arranged correspondingly, and the transparent unit 33 and the color filter unit 21 may be arranged correspondingly.

Further, the color of the color filter unit or the color of the light transmitted by the color filter unit may be same as the color of the light generated by the corresponding color conversion unit or the color of the light transmitted by the corresponding transparent unit. For example, the red color filter unit may be arranged corresponding to the color conversion unit that generates red light, the green color filter unit may be arranged corresponding to the color conversion unit that generates green light, and the blue color filter unit may be arranged corresponding to the transparent unit that transmits blue light. Using such a configuration, the light generated by the color conversion unit or the light transmitted by the transparent unit may emit after being filtered by the corresponding color filter unit.

In some embodiments of the present disclosure, when C2−C1>0, in the same color conversion unit, along the direction pointing toward color filter layer2, i.e., from away from the color filter layer 2 to adjacent to the color filter layer 2, the concentration of the color conversion material may gradually decrease, as shown in FIG. 3. FIG. 3 is a schematic cross-sectional view of another exemplary color film substrate consistent with various disclosed embodiments of the present disclosure. Along the direction indicated by the arrow X1, the concentration of the color conversion material may be gradually reduced. Under the premise to reduce the color cast issue, through the gradual change of the concentration of the color conversion material, the absorption of the excitation light by the color conversion layer 3 may be more uniform, and the distribution of the light generated by excitation may be more uniform, which may be more efficiency to improve the display effect.

In other embodiments, when C1−C2>0, in the same color conversion unit, along the direction from close to the color filter layer 2 to away from the color filter layer 2, in particular, along the opposite direction of the arrow X1, the concentration of the color conversion material may gradually decrease. In still other embodiments, when C1−C2>0, in the same color conversion unit, along the direction indicated by the arrow X1, the concentration of the color conversion material may gradually increase.

In one embodiment of the present disclosure, a color conversion layer 3 with the same concentration may be formed on the substrate 1 first, and then the color conversion material in different regions of the color conversion layer 3 may be processed by, an etching process, etc., to make the concentrations of the color conversion material in different regions of the color conversion layer 3 to be different and or gradually changed. In some embodiments, the entire color conversion layer 3 with the same concentration may be formed on the substrate 1, and then the color conversion material may be implanted into the color conversion layer 3 through processes such as an ion doping process, etc., such that the concentration of the color conversion material in different regions of the color conversion layer 3 may be different and/or gradually changed. The process for making the concentrations of the different regions of the color conversion layer 3 to be different is not limited in the present disclosure. In other embodiments, multiple sub-film layers with different concentrations may be formed on the substrate 1 to achieve different concentrations or gradual changes in different regions of the color conversion layer 3.

FIG. 4 is a schematic cross-sectional view of another exemplary color film substrate consistent with various disclosed embodiments of the present disclosure. As shown in FIG. 4, in one embodiment, the color conversion unit may include at least two sub-conversion layers. For example, the color conversion unit 31 may include at least two sub-conversion layers 310 and 311. The at least two sub-conversion layers 310 and 311 may be arranged in sequence along a direction from away from the color filter layer 2 to close to the color filter layer 2. In particular, along the direction indicated by the arrow X1, the sub-conversion layers 310 and 311 may be sequentially arranged.

Further, along the direction from away from the color filter layer 2 to close to the color filter layer 2, the concentration of the color conversion material in the same sub-conversion layer may gradually decrease, and the concentration of the color conversion material in different sub-conversion layers may also gradually decrease. In particular, along the direction indicated by the arrow X1, the concentration of the color conversion material in the sub-conversion layer 310 may gradually decrease, the concentration of the color conversion material in the sub-conversion layer 311 may gradually decrease, and the concentration of the color conversion material in the sub-conversion layer 310 may be less than that of the sub-conversion layer 311. On the premise that the color cast phenomenon may be reduced, and the color conversion layer 3 may absorb the excitation light more uniformly through the concentration gradient of the color conversion material, and the distribution of the excited light may be more uniform.

In other embodiments of the present disclosure, along the direction from away from the color filter layer 2 to close to the color filter layer 2, the concentration of the color conversion material in the same sub-conversion layer may gradually increase. The concentration of the color conversion material in different sub-conversion layers may also gradually increase, or decrease. In particular, along the direction indicated by the arrow X1, the concentration of the color conversion material in the sub-conversion layer 310 may gradually increases, the concentration of the conversion material in the sub-conversion layer 311 may gradually increases, and the concentration of the color conversion material in the sub-conversion layer 310 may be less than or greater than the concentration of the color conversion material in the sub-conversion layer 311. Accordingly, on the premise that the color cast phenomenon may be reduced, by gradually changing the concentration of the color conversion material, the absorption of the excitation light by the color conversion layer 3 may be more uniform, and the distribution of the light generated by the excitation light may be more uniform.

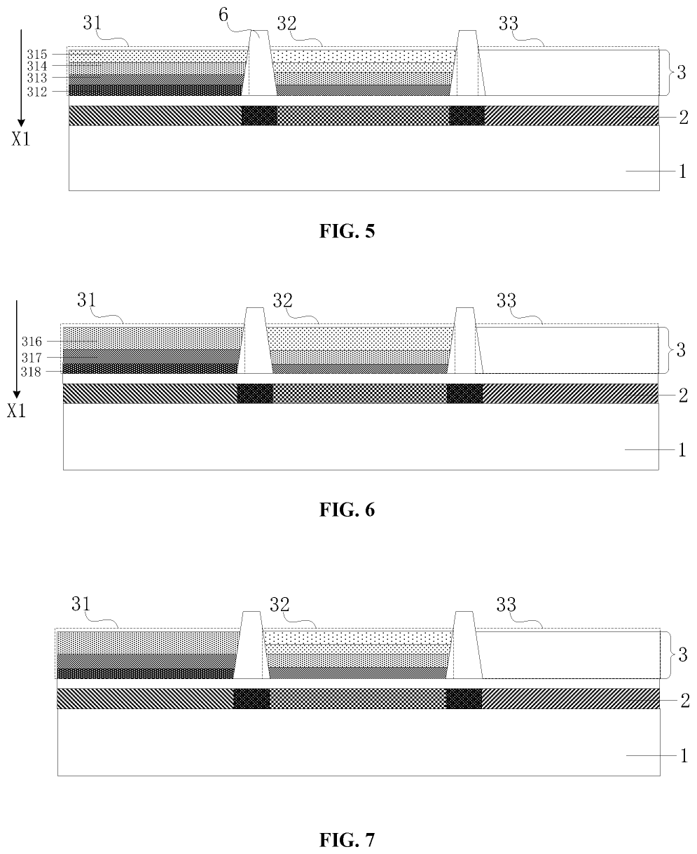

FIG. 5 is a schematic diagram of a cross-sectional view of another exemplary color film substrate consistent with various disclosed embodiments of the present disclosure. As shown in FIG. 5, in some embodiments, the color conversion unit may include at least two sub-conversion layers. Along the direction from away from the color resist layer 2 to close to the color resist layer 2, the sub-conversion layers may be arranged in sequence. For example, the color conversion unit 31 may include the sub-conversion layers 310, 311, 312, and 313. Along the direction indicated by the arrow X1, the sub-conversion layers 313, 312, 311, and 310 may be sequentially arranged.

Further, the concentration of the color conversion material in the same sub-conversion layer may be same, and the concentration of the color conversion material in different sub-conversion layers may be different. For example, the concentration of the color conversion material in the sub-conversion layer 313 may be uniform, but the concentrations of the color conversion material in the sub-conversion layer 310, 311, 312, and 313 may be different. Along the direction from away from the color filter layer 2 to close to the color filter layer 2, the concentration of the color conversion material in the sub-conversion layer may gradually decrease or may gradually increase. In particular, along the direction indicated by the arrow X1, the concentration of the color conversion materials in the sub-conversion layers 313, 312, 311, and 310 may be successively decreased or successively increased to achieve the gradual change of the concentration of the color conversion material. As the same time, the process difficulty may be reduced and the production cost may be reduced.

In the present disclosure, not only the color cast phenomenon may be reduced and the display effect may be improved through the difference or gradation of the color conversion material concentration, but also the color cast phenomenon may be reduced and the display effect may be improved through the difference in the thicknesses of the sub-color conversion layers.

FIG. 6 is a schematic cross-sectional view of another exemplary color film substrate consistent with various disclosed embodiments of the present disclosure. As shown in FIG. 6, in some embodiments based on the previously described embodiments, in a same color conversion unit, along the direction from away from the color filter layer 2 to close to the color filter layer 2, the thicknesses of the sub-conversion layers may gradually decrease. When the color conversion unit 31 includes the sub-conversion layers 316, 317, and 318, the thicknesses of the sub conversion layers 316, 317, and 318 may gradually decrease along the direction indicated by the arrow X1. Because the concentration of the color conversion material in different sub-conversion layers may be different, by gradually reducing the thickness of the sub-color conversion layer, on the basis of reducing the color cast phenomenon, the gradual reduction of the thicknesses of the sub-color conversion layers may further make the absorption of the excitation light by the color conversion layer 3 to be more uniform. Thus, the distribution of the light generated by the excitation light may be more uniform.

On the basis of any of the above embodiments, in other embodiments of the present disclosure, in the same color conversion unit, along the direction from away from the color filter layer 2 to close to the color filter layer 2, the thicknesses of the sub-conversion layers may also be gradually increased. In particular, along the direction indicated by the arrow X1, the thickness of the sub-conversion layers 316, 317, and 318 may be gradually increased.

In the present disclosure, the structure of the color conversion layer 3 in different color conversion units may be same to simplify the manufacturing process. However, because the color cast conditions of different types of color conversion units may be different, the color conversion layer 3 may be limited according to the color cast conditions of each color conversion unit to reduce the color cast condition of each color conversion unit.

FIG. 7 is a schematic cross-sectional view of another color film substrate consistent with various disclosed embodiments of the present disclosure. As shown FIG. 7, in some embodiments based on the previously described embodiments, in different types of the color conversion units, the number of sub-conversion layers may be different. For example, the number of sub-conversion layers in the color conversion unit 31 may be 3, and the number of sub-conversion layers in the color conversion unit 32 may be 4. By setting the number of sub-conversion layers to be different, the color cast phenomena in different types of color conversion units may be reduced to various degrees such that the color cast phenomenon of each color conversion unit may be reduced.

It should be noted that the concentration of the color conversion material in each sub-conversion layer may be same, or it may be gradually increased or decreased, and the concentration of the color conversion material in different sub-conversion layers may be gradually increased or decreased.

On the basis of any of the above-mentioned embodiments, in other embodiments of the present disclosure, the number of sub-conversion layers in different types of color conversion units may be the same. However, the thicknesses of the sub-conversion layers in the same layer may be different, and/or, the concentrations or the concentration ranges of the color conversion material in the sub-conversion layers in the same layer may be different.

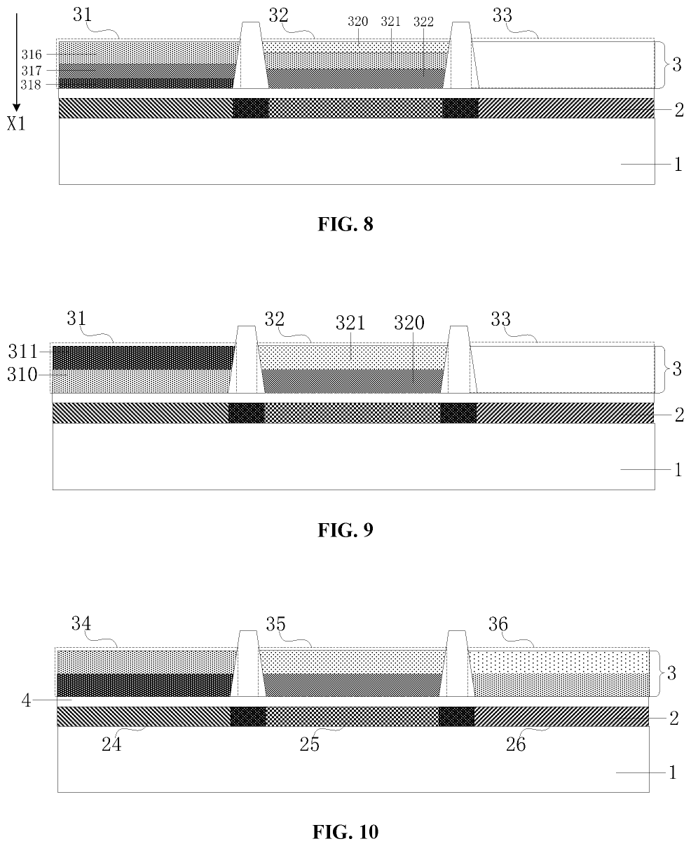

FIG. 8 is a schematic diagram of a cross-sectional view of another exemplary color film substrate consistent with various disclosed embodiments of the present disclosure. As shown in FIG. 8, the color conversion unit 31 may include sub-conversion layers 316, 317, and 318, and the color conversion unit 32 may include sub-conversion layers 320, 321, and 322. The number of sub-conversion layers in the color conversion unit 31 and the number of sub-conversion layers in the color conversion unit 32 may be same. However, when the concentrations of the color conversion material in the same sub-conversion layers are same, the thicknesses of the same sub-conversion layers, such as 316 and 320, may be different, and/or the concentrations of the color conversion material may be different. In some embodiments, when the concentration of the color conversion material in the same sub-conversion layer gradually increases or decreases, the thicknesses of the same sub-conversion layer, such as 316 and 320, may be different and/or the concentration ranges of the color conversion material may be different. By setting the thicknesses and/or the concentrations of the sub-conversion layers to be different, or setting the thicknesses and/or the concentration ranges of the sub-conversion layers to be different, the color cast phenomenon of different types of color conversion units may be reduced to various degrees, and the color cast phenomenon of each color conversion unit may be effectively reduced.

In one embodiment, along the direction from away from the color filter layer 2 to close to the color filter layer 2, the thicknesses of the sub-conversion layers in one color conversion unit may gradually decrease, and the thicknesses of the sub-conversion layers in the other color conversion unit may gradually increase. In particular, along the direction indicated by the arrow X1, the thicknesses of the sub-conversion layers 316, 317, and 318 may gradually decrease, and the thicknesses of the sub-conversion layers 320, 321, and 322 may gradually increase. In some embodiments, along the direction indicated by the arrow X1, the thicknesses of the sub-conversion layers 316, 317, and 318 may gradually increase, and the thicknesses of the sub-conversion layers 320, 321, and 322 may gradually decreases.

Further, on the basis of such a configuration, along the direction from away from the color filter layer 2 to close to the color filter layer 2, the concentrations or concentration ranges of the color conversion material of the sub-conversion layers in one color conversion unit may be gradually decreased, and the concentrations or concentration ranges of the color conversion material of the sub-conversion layers in other color conversion units may gradually decrease. For example, along the direction indicated by the arrow X1, the concentrations or concentration ranges of the color conversion material of the sub-conversion layers 316, 317, and 318 may gradually decrease, and the concentrations or concentration ranges of the color conversion material of the sub-conversion layers 320, 321, and 322 may gradually increases. In some embodiments, the concentrations or concentration ranges of the color conversion material of the sub-conversion layers 316, 317, and 318 may gradually increase, and the concentrations or concentration ranges of the color conversion material of the sub-conversion layers 320, 321, and 322 may gradually decrease. For such configurations, while achieving the thicknesses and/or the concentrations of the sub-conversion layers to be different, the thicknesses and/or concentrations of the sub-conversion layers may be gradually changed, or the thicknesses and/or concentration ranges of the sub-conversion layers may be gradually changed. Thus, the absorption of the color conversion layer 3 to the excitation light may be more uniform, and the distribution of light generated by the excitation light may be more uniform.

In some embodiments of the present disclosure, the color conversion layer 3 may at least include a first type of color conversion units and a second type of color conversion unit. In the first type of color conversion units, C2−C1>0. In the second type of color conversion units, C2−C1<0.

FIG. 9 is a schematic cross-sectional view of another exemplary color film substrate consistent with various disclosed embodiments of the present disclosure. As shown in

FIG. 9, when the concentration of the color conversion material 310 on the side of the color conversion layer 3 adjacent to the color filter layer 2 in the color conversion unit 31 is C1, and the concentration of the color conversion material 311 on the side of the color conversion layer 3 away from the color filter layer 2 is C2, C2−C1>0. When the concentration of the color conversation material 320 on the side of the color conversion layer 3 in the color conversion unit 32 adjacent to the color filter layer 2 is C1, and the concentration of the color conversion material 321 on the side of the color conversion layer 3 away from the color filter layer 2 is C2, C2−C1<0.

Although that C1−C2>0 or C2−C1>0 may all effectively reduce the color cast phenomenon of the color conversion layer 3, there may be differences in the effect of reducing the color cast of the color conversion layer 3 between the two methods. Thus, in some embodiments of the present disclosure, by setting C2−C1>0 in the first color conversion unit and C2−C1<0 in the second color conversion unit, the color cast of different types of color conversion units may be reduced with different degrees, and the color cast phenomenon of each color conversion unit may be effectively reduced.

Further, on the basis of any of the foregoing embodiments, in some embodiments of the present disclosure, different types of color conversion units may have different types of color conversion materials. For example, the color conversion material of the color conversion unit 31 is one material, and the color conversion material in the color conversion unit 32 may be another material. Among them, the color conversion materials may include a quantum dot material and a fluorescent material, etc. In one embodiment, the color conversion materials in one color conversion unit may be a quantum dot material, and the color conversion material in another color conversion unit may be a fluorescent material. For example, the color conversion material in the color conversion unit 31 may be a quantum dot material, and the color conversion material in the color conversion unit 32 may be a fluorescent material. Thus, the color cast phenomenon of different types of color conversion units may be reduced to different degrees such that the color cast phenomenon of each color conversion unit may be effectively reduced.

If the color cast phenomenon of the blue light generated by the quantum dot material is small, the color conversion material of the color conversion unit that generates the blue light may be a quantum dot material. If the color cast phenomenon of the red light generated by the fluorescent material is small, the color conversion material of the color conversion unit that generates the red light may be a fluorescent material. In some embodiments of the present disclosure, the color conversion materials of the color conversion units may be limited according to specific conditions.

In some embodiments of the present disclosure, the excitation light may be light of a first color. In the area corresponding to each pixel unit 5, the color conversion layer 3 may include two color conversion units and a transparent unit. As shown in FIG. 2, the color conversion layer 3 may include a first color conversion unit 31, a second color conversion unit 32, and a transparent unit 33. The color conversion material in the first color conversion unit 31 may be excited by the light of the first color to produce the light of the second color. The color conversion material in the second color conversion unit may be excited by the light of the first color to generate the light of the third color, and the transparent unit 33 may transmit the light of the first color.

The color filter layer 2 may include a color filter unit 21 of a first color, a color filter unit 22 of a second color, and a color filter unit 23 of a third color. The color filter unit 21 of the first color may be arranged corresponding to the transparent unit 33 for transmitting the light of the first color; the color filter unit 22 of the second color may be arranged corresponding to the first color conversion unit 31 for transmitting the light of the second color; and the color filter unit 23 of the third color may be arranged corresponding to the second color conversion unit 32 for transmitting the light of the third color. Using such a configuration, the light of the first color, the light of the second color, and the light of the third color may perform the image display.

In one embodiment, the light of the first color may be blue light, the light of the second color and the light of the third color may be red light and green light, respectively. The colors of the light in the present disclosure are not specifically limited. In some embodiments, the light of the first color may also be ultraviolet light, and the light of the second color and the light of the third color may also be yellow light and blue light, respectively.

In the structures shown in FIGS. 1-9, the configuration that, in the area corresponding to each pixel unit 5, the color conversion layer 3 may include two color conversion units and a transparent unit is used as an example for description. In some embodiments, in the region corresponding to each pixel unit 5, the color conversion layer 3 may include three color conversion units, such as color conversion units that generate red light, green light, and blue light, respectively.

FIG. 10 is a schematic cross-sectional view of another exemplary color filter consistent with various disclosed embodiments of the present disclosure. As shown in FIG. 10, the excitation light may be the light of a first color, and the color conversion layer 3 may include a first color conversion unit 34, a second color conversion unit 35 and a third color conversion unit 36. The color conversion material in the first color conversion unit 34 may be excited by the light of the first color to produce light of the second color. The color conversion material in the second color conversion unit 35 may be excited by the light of the first color to generate the light of the third color. The color conversion material in the third color conversion unit 36 may be excited by the light of the first color to generate light of the fourth color.

The color filter layer 2 may include a color filter unit 24 of a second color, a color filter unit 25 of a third color, and a color filter unit 26 of a fourth color. The color filter unit 24 of the second color and the first color conversion unit 34 may be arranged correspondingly to transmit the light of the second color. The color filter unit 25 of the third color and the second color conversion unit 35 may be arranged correspondingly to transmit light of the third color. The color filter unit 26 of the fourth color and the third color conversion unit 36 may be arranged correspondingly to transmit the light of the fourth color. Such a configuration may allow the light of the second color, the light of the third color, and the light of the fourth color to perform the image display.

In one embodiment, the light of the first color may be ultraviolet light, and the light of the second color, the light of the third color, and the light of the fourth color may be red light, green light, and blue light, respectively. The colors of the lights are not limited in the present disclosure. In some embodiments, the light of the first color may also be white light, etc.

Further, in other embodiments of the present disclosure, the color conversion layer 3 may include four color conversion units, such as color conversion units that generate red light, green light, blue light, and white light, respectively, or the color conversion units that generate red light, green light, blue light and yellow light.

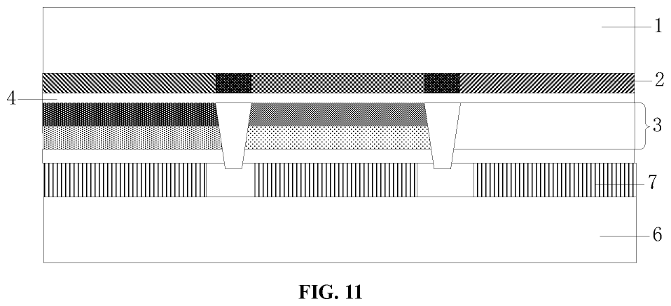

The present disclosure also provides a display panel. FIG. 11 is a schematic cross-sectional view of an exemplary display panel consistent with various disclosed embodiments of the present disclosure. As shown in FIG. 11, the display panel may include a color film substrate and an array substrate opposing to the color film substrate.

The color film substrate may be the color film substrate provided in any of the above embodiments or other appropriate color film substrate. The array substrate may include a substrate 6 and a light-emitting element 7 on the substrate 6 and a driving circuit for driving the light-emitting element 7. Among them, the light-emitting element 7 may be configured to emit the excitation light, and the excitation light may be configured to excite the color conversion unit to generate light of a corresponding color.

The side of the color film substrate having a color conversion unit, e.g., the side with the color conversion layer 3, may be disposed adjacent to the side of the array substrate having the light-emitting element 7 such that the excitation light emitted by the light-emitting element 7 may be able to irradiate the color conversion layer 3 to excite the color conversion material of the color conversion unit in the color conversion layer 3 to generate light of a corresponding color. The generated light may be configured to display an image.

In some embodiments of the present disclosure, the excitation light emitted by the light-emitting element 7 may include light of a first color, and the light of the first color may include blue light or ultraviolet light, etc. For example, in some embodiments of the present disclosure, the excitation light emitted by the light-emitting element 7 may be blue light. The color conversion layer 3 may include two color conversion units and a transparent unit. The two color conversion units may generate red light and green light, respectively, and the transparent unit may transmit blue light to cause the red light, the green light and the blue light to display image.

In one embodiment of the present disclosure, the light-emitting element 7 may include light-emitting diode (LED), organic light-emitting diode (OLED), or Micro-LED, etc. Optionally, the light-emitting element 7 may be a Micro-LED, and each Micro-LED may be corresponding to a color conversion unit or a transparent unit to excite or transmit the corresponding light.

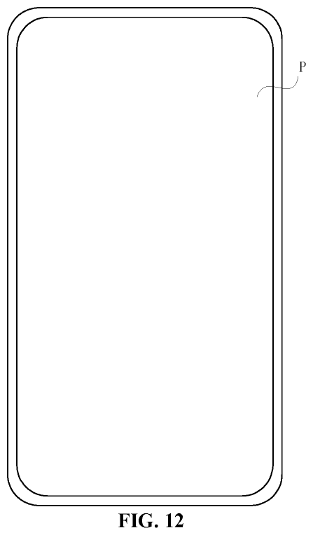

Further, the present disclosure provides a display device. FIG. 12 is a schematic diagram of an exemplary display device consistent with various disclosed embodiments of the present disclosure. As shown in FIG. 12, the display device P may include a display panel. The display panel may be the display panel provided in any of the above embodiments, or other appropriate display panel. The display device P may include, but not limit to, smart phone, tablet computer, or digital camera, etc.

The various embodiments in this specification are described in a progressive manner. Each embodiment focuses on the differences from other embodiments, and the same or similar parts between the various embodiments can be referred to each other. For the device disclosed in the embodiment, since it corresponds to the method disclosed in the embodiment, the description is relatively simple, and the relevant part can be referred to the description of the method part.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A color film substrate, comprising:
a substrate;
a color filter layer disposed on the substrate; and
a color conversion layer disposed on a side of the color filter layer away from the substrate,
wherein:
the color film substrate is correspondingly disposed with an array substrate having a plurality of pixel units;
in an area of the color conversion layer corresponding to each pixel unit of the plurality of pixel units, the color conversion layer includes at least two color conversion units;
colors of lights generated by exciting color conversion materials of different color conversion units of the at least two color conversion units by excitation light are different; and
in a same color conversion unit of the at least two color conversion units, a concentration of a color conversion material in a side of the color conversion layer adjacent to the color filter layer is C₁, a concentration of a color conversion material in a side of the color conversion layer away from the color filter layer is C₂, and |C₁−C₂|>0.

2. The color film substrate according to claim 1, wherein:
C₂−C₁>0.

3. The color film substrate according to claim 1, wherein:
in the same color conversion unit, along a direction from away from the color filter layer to adjacent to the color filter layer, the concentration of the color conversion material is gradually reduced.

4. The color film substrate according to claim 3, wherein:
the same color conversion unit includes at least two sub-conversion layers;
along the direction from away from the color filter layer to adjacent to the color filter layer, the at least two sub-conversion layers are sequentially arranged;
the color conversion material in the same color conversion unit has a same concentration;
the color conversion material in the different color conversion units has different concentration; and
along the direction from away from the color filter layer to adjacent to the color filter layer, the concentration of color conversion materials in the at least two sub-color conversion layers are gradually reduced.

5. The color film substrate according to claim 3, wherein:
the same color conversion unit includes at least two sub-conversion layers;
along the direction from away from the color filter layer to adjacent to the color filter layer, the at least two sub-conversion layers are sequentially arranged; and
along the direction from away from the color filter layer to adjacent to the color filter layer, the concentration of the color conversion material in a sub-color conversion layer is gradually reduced, and the concentration of the color conversion material in different sub-conversion layers are gradually reduced.

6. The color film substrate according to claim 5, wherein:
in the same color conversion unit, along the direction from away from the color filter layer to adjacent to the color filter layer, thicknesses of the at least two sub-conversion layers are gradually reduced.

7. The color film substrate according to claim 5, wherein:
numbers of the sub-conversion layers in different types of color conversion units are different.

8. The color film substrate according to claim 5, wherein:
numbers of the sub-color conversion layers in different types of color conversion units are same;
thicknesses of the at least two sub-conversion layers in a same layer are different; and/or
concentrations or concentration ranges of color conversion materials of the at least two sub-color conversion layers in a same layer are different.

9. The color film substrate according to claim 1, wherein:
the color conversion layer at least includes a first type of color conversion units and a second type of color conversion units;
in the first type of color conversion units, C₂−C₁>0; and
in the second type of color conversion units, C₂−C₁<0.

10. The color film substrate according to claim 1, wherein:
types of color conversion materials in different types of color conversion units are different.

11. The color film substrate according to claim 10, wherein:
the color conversion material in one type of color conversation units is a quantum dot material; and
the color conversion material in another type of color conversion units is a fluorescence material.

12. The color film substrate according to claim 1, wherein:
the excitation light is light of a first color;
the color conversion layer includes a first color conversion unit, a second color conversion unit and a transparent unit;
a color conversion material in the first color conversion unit is excited by the light of the first color to generate light of a second color;
a color conversion material in the second color conversion unit is excited by the light of the first color to generate light of a third color;
the transparent unit is configured to transmit the light of the first color;
the color filter layer includes a color filter unit of a first color, a color filter unit of a second color and a color filter unit of a third color;
the color filter unit of the first color is correspondingly disposed with the transparent unit to transmit the light of the first color;
the color filter unit of the second color is correspondingly disposed with the first conversion unit to transmit the light of the second color; and
the color filter unit of the third color is correspondingly disposed with the second color conversion unit to transmit the light of the third color.

13. The color film substrate according to claim 12, wherein:
the light of the first color is blue light;
the light of the second color is red light; and
the light of the third color is green light.

14. The color film substrate according to claim 1, wherein:
the excitation light is light of a first color,
the color conversion layer includes a first color conversion unit, a second color conversion unit and a third color conversion unit;
a color conversion material in the first color conversion unit is excited by the light of the first color to generate light of a second color;
a color conversion material in the second color conversion unit is excited by the light of the first color to generate light of a third color;
a color conversion material in the third color conversion unit is excited by the light of the first color to generate light of a fourth color;
the color filter layer includes a color filter unit of a second color and a color filter unit of a third color and a color filter of a fourth color;
the color filter unit of the second color is correspondingly disposed with the first color conversion unit to transmit the light of the second color;
the color filter unit of the third color is correspondingly disposed with the second color conversion unit to transmit the light of the third color; and
the color filter unit of the fourth color is correspondingly disposed with the third color conversion unit to transmit the light of the fourth color.

15. The color film substrate according to claim 13, wherein:
the light of the first color is ultraviolet light;
the light of the second color is red light;
the light of the third color is green light; and
the light of the fourth color is blue light.

16. A display panel, comprising:
a color film substrate; and
an array substrate disposed opposing to the color film substrate,
wherein:
the color film substrate includes:
a substrate;
a color filter layer disposed on the substrate; and
a color conversion layer disposed on a side of the color filter layer away from the substrate,
wherein:
the array substrate includes a plurality of pixel units;
in an area of the color conversion layer corresponding to each pixel unit of the plurality of pixel units, the color conversion layer includes at least two color conversion units;
colors of lights generated by color conversion materials of different color conversion units excited by excitation light are different; and
in a same color conversion unit, a concentration of a color conversion material in a side of the color conversion layer adjacent to the color filter layer is C₁, a concentration of a color conversion material in a side of the color conversion layer away from the color filter layer is C₂, and |C₁−C₂|>0;
a side of the color filter substrate having the color conversion unit is disposed adjacent to a side of the array substrate having a light-emitting component;
the light-emitting component is configured to emit the excitation light; and
the excitation light is used to excite the color conversion unit to generate light of a corresponding color.

17. The display panel according to claim 16, wherein:
the excitation layer generated by the light-emitting component includes light of a first color; and
the light of the first color includes blue light and ultraviolet light.

18. The display panel according to claim 16, wherein:
the light-emitting component includes a light-emitting diode (LED), an organic light-emitting diode (OLED), or a micro light-emitting diode (Micro-OLED).

19. A display device, comprising:
a display panel, including:
a color film substrate; and
an array substrate disposed opposing to the color film substrate, wherein:
the color film substrate includes:
a substrate;
a color filter layer disposed on the substrate; and
a color conversion layer disposed on a side of the color filter layer away from the substrate,
wherein:
the array substrate includes a plurality of pixel units;
in an area of the color conversion layer corresponding to each pixel unit, the color conversion layer includes at least two color conversion units;
colors of lights generated by color conversion materials of different color conversion units excited by excitation lights are different; and
in a same color conversion unit, a concentration of color conversion material at a side of the color conversion layer adjacent to the color filter layer is C₁, a concentration of color conversion material at a side of the color conversion layer away from the color filter layer is C₂, and |C₁−C₂|>0;
a side of the color film substrate having the color conversion unit is disposed adjacent to a side of the array substrate having a light-emitting component;
the light-emitting component is configured to emit the excitation light; and
the excitation light is used to excite the color conversion unit to generate light of a corresponding color.
